(19) United States
(12) Patent Application Publication
(10) Pub. No.: US 2006/0202866 A1
(43) Pub. Date: Sep. 14, 2006

(54) Handheld electronic device having improved display and selection of disambiguation choices, and associated method

(76) Inventor: Krishna K. Pathiyal, Waterloo (CA)

Correspondence Address: ECKERT SEAMANS CHERIN & MELLOTT, 600 GRANT STREET, 44TH FLOOR, PITTSBURGH, PA, 15219, US

(21) Appl. No.: 11/074,571

(22) Filed: Mar. 8, 2005

(51) Int. Cl. H03M 11/00; H03K 17/94

(52) U.S. Cl. 341/22; 341/28

(57) ABSTRACT

A method of entering information into an electronic device, such as a handheld electronic device, that has a text disambiguation function, a keyboard and a display. The method includes generating a plurality of character combination choices using the text disambiguation function based on a first key depression sequence input into the electronic device, and displaying the character combination choices in a first spatial arrangement on the display. The first spatial arrangement substantially corresponds to a second spatial arrangement of a plurality of keys provided on a portion of the keyboard, and each one of the character combination choices corresponds to a particular one of the keys. The method further includes selecting and inputting a particular one of the character combination choices when the particular one of the keys that corresponds to the particular one of the character combination choices is depressed. Also, an electronic device that implements the method.

### BACKGROUND OF THE INVENTION

1. Field of the Invention

The invention relates generally to electronic devices employing a text disambiguation function, and, more particularly, to a handheld electronic device having an improved manner of displaying and enabling the selection of character combination choices generated by a text disambiguation function. The invention also relates to an improved method of displaying and enabling the selection of character combination choices generated by a text disambiguation function.

2. Background Information

Numerous types of handheld electronic devices are known. Examples of such handheld electronic devices include, for instance, personal data assistants (PDAs), handheld computers, two-way pagers, cellular telephones, and the like. Many handheld electronic devices also feature wireless communication capability, although many such handheld electronic devices are stand-alone devices that are functional without communication with other devices.

Such handheld electronic devices are generally intended to be portable, and thus are of a relatively compact configuration in which keys and other input structures often perform multiple functions under certain circumstances or may otherwise have multiple aspects or features assigned thereto. With advances in technology, handheld electronic devices are built to have progressively smaller form factors yet have progressively greater numbers of applications and features resident thereon. As a practical matter, the keys of a keypad can only be reduced to a certain small size before the keys become relatively unusable. In order to enable text entry, however, a keypad must be capable of entering all twenty-six letters of the Roman alphabet, for instance, as well as appropriate punctuation and other symbols.

One way of providing numerous letters in a small space has been to provide a “reduced keyboard” in which multiple letters, symbols, and/or digits, and the like, are assigned to any given key. For example, a touch-tone telephone includes a reduced keyboard by providing twelve keys, of which ten have digits thereon, and of these ten keys, eight have Roman letters assigned thereto. For instance, one of the keys includes the digit “2,” as well as the letters “A”, “B”, and “C”. Since a single actuation of such a key potentially could be intended by the user to refer to any of the letters “A”, “B”, and “C”, and potentially could also be intended to refer to the digit “2”, the input (by actuation of the key) generally is an ambiguous input and is in need of some type of disambiguation in order to be useful for text entry purposes. Other known reduced keyboards have included other arrangements of keys, letters, symbols, digits, and the like. One example of a reduced keyboard is the keypad 24 forming a part of the handheld electronic device 4 shown in FIG. 1 and described in greater detail herein. Keypad 24 is what is known as a reduced QWERTY keyboard.

In order to enable a user to make use of the multiple letters, digits, and the like on any given key in an ambiguous keyboard, numerous keystroke interpretation systems have been provided. For instance, a “multi-tap” system allows a user to substantially unambiguously specify a particular character on a key by pressing the same key a number of times equivalent to the position of the desired character on the key. For example, on the aforementioned telephone key that includes the letters “ABC”, if the user desires to specify the letter “C”, the user will press the key three times. Similarly, on the aforementioned keypad 24, if the user desires to specify the letter “C”, the user will press the key that includes “CV7” once, and if the user desires to specify the letter “I”, the user will press the key that includes “UI3” two times.

Another exemplary keystroke interpretation system would include key chording, of which various types exist. For instance, a particular character can be entered by pressing two keys in succession or by pressing and holding a first key while pressing a second key. Still another exemplary keystroke interpretation system would be a “press-and-hold/press-and-release” interpretation function in which a given key provides a first result if the key is pressed and immediately released, and provides a second result if the key is pressed and held for a short period of time.

Another keystroke interpretation system that has been employed is a software-based text disambiguation function. In such a system, a user typically presses keys to which one or more characters have been assigned, generally pressing each key one time for each desired letter, and the disambiguation software attempts to predict the intended input. Numerous such systems have been proposed. One example of such a system is disclosed in commonly owned U.S. patent application Ser. No. 10/931,281, entitled “Handheld Electronic Device With Text Disambiguation,” the disclosure of which is incorporated herein by reference. As is known, many such systems display an output component as the user is typing (pressing keys) that includes a list of possible intended input character strings (i.e., what the user intended while typing) that are generated by the disambiguation software. For example, FIG. 1 shows a display 60 that may be provided by the disambiguation software system described in the aforementioned commonly owned U.S. patent application Ser. No. 10/931,281. As described in greater detail herein, FIG. 1 shows an exemplary output 64 being depicted on the display 60 that includes a text component 68 and a variant component 72. The variant component 72 includes a default portion 76 and a variant portion 80. The variant component 72 represents a list of possible intended inputs (in the form of a number of character strings or combinations) as generated by the disambiguation software. A user may select one of the items listed in the variant component 72 for inclusion in the final text component 68.

In many current software-based text disambiguation systems, the output component that includes the list of possible intended inputs that is generated by the disambiguation software, such as a variant component 72, is presented as a single line of text. In order to select a particular one of the possible intended inputs, a user must typically execute a number of affirmative actions, such as scrolling a thumbwheel or pressing a predetermined function button. For example, FIG. 3 shows an example of a prior art output containing a prior art variant component 72 that may appear on a display such as a display 60 in a situation where the list of possible intended inputs (possible character strings or combinations) that is generated by the disambiguation software is provided on a single line. In order to select the character string “is” from the list of possible intended inputs, a user of handheld electronic device 4 will have to either (i) scroll the thumbwheel to a large enough extent to move the “highlighting” over the character string “is” and then press an enter key or the like, or (ii) press a function button such as the <NEXT> key 40 shown in FIG. 1 a sufficient number of time to move the “highlighting” over the character string “is” and then press an enter key or the like, both of which require a number of different user operations and thus require user time and attention. In addition, when the number of possible intended inputs that is generated by the disambiguation software is so large that all of them cannot fit on a single line of the display, the list is typically continued on one or more additional screens (each screen having a single line of text containing possible intended input choices), and the user must take some action, such as scrolling a thumbwheel or pressing a predetermined function button such as the <NEXT> key 40, to move from one screen to the next to view all of the choices. Once on the desired screen, the steps described above must be taken to select a particular one of the listed possible intended inputs. Again, all of these actions are time consuming and inconvenient for the user. Thus, a method is needed for electronic devices that employ text disambiguation software that simplifies and shortens the procedure required to select a possible intended input generated by the disambiguation software.

### SUMMARY OF THE INVENTION

The invention, in one aspect, relates to a method of entering information into an electronic device, such as a handheld electronic device, that has a text disambiguation function, a keyboard and a display. The method includes generating a plurality of character combination choices using the text disambiguation function based on a first key depression sequence input into the electronic device, and displaying the character combination choices in a first spatial arrangement on the display. The first spatial arrangement substantially corresponds to a second spatial arrangement of a plurality of keys provided on a portion of the keyboard, and each one of the character combination choices corresponds to a particular one of the keys. The method further includes selecting and inputting a particular one of the character combination choices when the particular one of the keys that corresponds to the particular one of the character combination choices is depressed. Preferably, the plurality of keys comprise the keys that have the numbers 1 through 9 provided thereon as seen in FIG. 4. Also, the second spatial arrangement preferably comprises three rows, each row having three of the keys.

In another aspect, the invention relates to an electronic device having a keyboard having a plurality of keys, a display, a processor, and a memory storing one or more routines executable by the processor. The one or more routines stored in the memory implement a text disambiguation function. In addition, the one or more routines are adapted to implement the various embodiments of the invention as described herein to enable the simplified selection of character combination choices generated by the text disambiguation function.

### BRIEF DESCRIPTION OF THE DRAWINGS

A full understanding of the invention can be gained from the following Description of the Preferred Embodiments when read in conjunction with the accompanying drawings in which:

FIG. 1 is a front view of an improved handheld electronic device in accordance with the invention;

FIG. 2 is a block diagram of the handheld electronic device of FIG. 1;

FIG. 3 is an exemplary prior art screen provided on a display of a handheld electronic that displays character combination choices generated by a text disambiguation function; and

FIG. 4 is an exemplary screen provided on a display of the handheld electronic shown in FIGS. 1 and 2 along with a schematic representation of a portion of a keypad of the handheld electronic shown in FIGS. 1 and 2 wherein the screen displays and enables the selection of character combination choices generated by a text disambiguation function according to the invention;

Similar numerals refer to similar parts throughout the specification.

### DESCRIPTION OF THE PREFERRED EMBODIMENTS

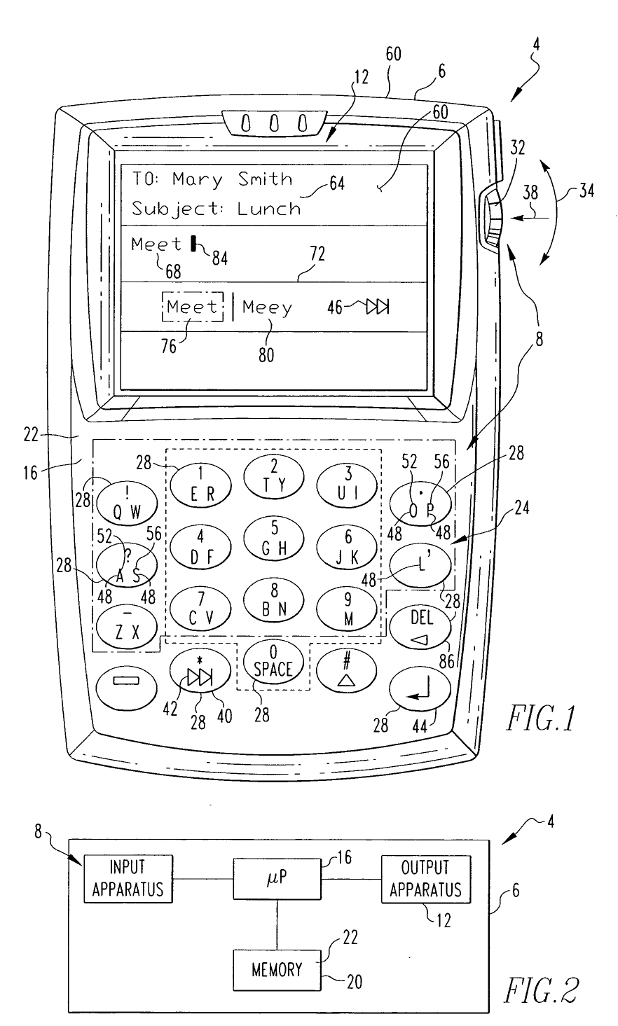

An improved handheld electronic device 4 is indicated generally in FIG. 1 and is depicted schematically in FIG. 2. The exemplary handheld electronic device 4 includes a housing 6 upon which are disposed a processor unit that includes an input apparatus 8, an output apparatus 12, a processor 16, and a memory 20. The processor 16 may be, for instance, and without limitation, a microprocessor (μP) and is responsive to inputs from the input apparatus 8 and provides output signals to the output apparatus 12. The processor 16 also interfaces with the memory 20. Examples of handheld electronic devices are included in U.S. Pat. Nos. 6,452,588 and 6,489,950, the disclosures of which are incorporated by reference herein.

As can be understood from FIG. 1, the input apparatus 8 includes a keypad 24 and a thumbwheel 32. The keypad 24 is in the exemplary form of a reduced QWERTY keyboard including a plurality of keys 28 that serve as input members. It is noted, however, that the keypad 24 may be of other reduced configurations, such as a reduced AZERTY keyboard, a reduced QWERTZ keyboard, or other keyboard arrangement, whether presently known or unknown. In this regard, the expression “reduced” and variations thereof, in the context of a keyboard, such as a keypad or other arrangement of input members, shall refer broadly to an arrangement in which at least one of the input members has assigned thereto a plurality of characters within a given set, such as a plurality of letters, for example, in the set of Roman letters, for example, thereby rendering ambiguous an intended result of an actuation of the at least one of the input members. In addition, as used herein, the expression “key” and variations thereof shall refer broadly to any of a variety of input members such as buttons, switches, and the like without limitation.

In this regard, and as will be set forth below in greater detail, the system architecture of the handheld electronic device 4 advantageously is organized to be operable independent of the specific layout of the keypad 24. Accordingly, the system architecture of the handheld electronic device 4 can be employed in conjunction with virtually any keyboard layout substantially without requiring any meaningful change in the system architecture.

The keys 28 are disposed on a front face of the housing 6, and the thumbwheel 32 is disposed at a side of the housing 6. The thumbwheel 32 can serve as another input member and is both rotatable, as is indicated by the arrow 34, to provide selection inputs to the processor 16, and also can be pressed in a direction generally toward the housing 6, as is indicated by the arrow 38, to provide another selection input to the processor 16.

Among the keys 28 of the keypad 24 are a <NEXT> key 40 and an <ENTER> key 44. The <NEXT> key 40 can be pressed to provide a selection input to the processor 16 and provides substantially the same selection input as is provided by a rotational input of the thumbwheel 32. Since the <NEXT> key 40 is provided adjacent a number of the other keys 28 of the keypad 24, the user can provide a selection input to the processor 16 substantially without moving the user's hands away from the keypad 24 during a text entry operation. As seen in FIG. 1, the <NEXT> key 40 additionally and advantageously includes a graphic 42 disposed thereon, and in certain circumstances the output apparatus 12 also displays a displayed graphic 46 thereon to identify the <NEXT> key 40 as being able to provide a selection input to the processor 16. In this regard, the displayed graphic 46 of the output apparatus 12 is substantially similar to the graphic 42 on the <NEXT> key and thus identifies the <NEXT> key 40 as being capable of providing a desirable selection input to the processor 16.

As can further be seen in FIG. 1, many of the keys 28 include a number of characters 48 disposed thereon. As employed herein, the expression “a number of” and variations thereof shall refer broadly to any quantity, including a quantity of one, and in certain circumstances herein can also refer to a quantity of zero. In the exemplary depiction of the keypad 24, many of the keys 28 include two or more characters, such as including a first character 52 and a second character 56 assigned thereto. It is understood that the expression “characters” shall broadly be construed to include letters, digits, symbols and the like and can additionally include ideographic characters, components thereof, other linguistic elements, and the like. The keys 28 having one or more characters 48 can be considered to be linguistic input members.

One of the keys 28 of the keypad 24 includes as the characters 48 thereof the letters “Q” and “W”, and an adjacent key 28 includes as the characters 48 thereof the letters “E” and “R”. It can be seen that the arrangement of the characters 48 on the keys 28 of the keypad 24 is generally of a QWERTY arrangement, albeit with many of the keys 28 including two of the characters 48.

The memory 20 is depicted schematically in FIG. 2. The memory 20 can be any of a variety of types of internal and/or external storage media, alone or in combination, such as, without limitation, RAM, ROM, EPROM(s), EEPROM(s), and the like that provide a storage register for data storage such as in the fashion of an internal storage area of a computer, and can be volatile memory or nonvolatile memory. The memory 20 additionally includes a number of routines depicted generally with the numeral 22 for the processing of data. The routines 22, executable by the processor 16, can be in any of a variety of forms such as, without limitation, software, firmware, and the like. The routines 22 include a software-based text disambiguation function as described elsewhere herein as an application, as well as other routines. The software-based text disambiguation function may, in one embodiment, be as described in commonly owned U.S. patent application Ser. No. 10/931,281, entitled “Handheld Electronic Device With Text Disambiguation,” the disclosure of which is incorporated herein by reference. In addition, the routines 22 may also include a non-predictive keystroke interpretation system, such as a “multi-tap” system, that allows a user to substantially unambiguously specify a particular character 48 on a particular key 28 by pressing the same key 28 a number of times equivalent to the position of the desired character 48 on the key 28.

The output apparatus 12 includes a display 60 upon which can be provided an output 64. An exemplary output 64 is depicted on the display 60 in FIG. 1. The output 64 includes a text component 68 and a variant component 72. The variant component 72 includes a default portion 76 and a variant portion 80. The display also includes a cursor 84 that depicts generally where the next input from the input apparatus 8 will be received.

The text component 68 of the output 64 provides a depiction of the default portion 76 of the output 64 at a location on the display 60 where the text is being input. The variant component 72 is disposed generally in the vicinity of the text component 68 and provides, in addition to the default proposed output 76, a depiction of the various alternate character combination choices, i.e., alternates to the default proposed output 76, that are proposed by the text disambiguation function in response to an input sequence of key actuations of the keys 28.

As described in detail in commonly owned U.S. patent application Ser. No. 10/931,281, entitled “Handheld Electronic Device With Text Disambiguation,” the default portion 76 is proposed by the text disambiguation function as being the most likely disambiguated interpretation of the ambiguous input provided by the user. The variant portion 80 includes a predetermined quantity of alternate proposed interpretations of the same ambiguous input from which the user can select, if desired.

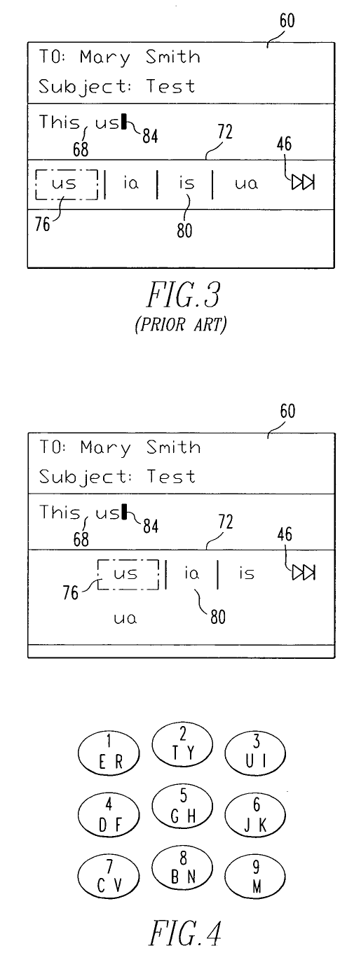

Referring to FIG. 4, which is an exemplary output provided on display 60 along with a schematic representation of a portion of keypad 24, the variant component 72 is, according to the invention, provided in a manner that facilitates and simplifies the selection of one of the character combination choices included therein. In particular, the character combination choices included in variant component 72 are arranged in a way that substantially matches the spatial arrangement of the keys 28 of a particular, predetermined portion of keypad 24. In the preferred embodiment of the invention, the character combination choices included in variant component 72 are arranged in a way that substantially matches the spatial arrangement of the keys 28 that include the numerals 1 through 9 thereon. As a result, a user may select a particular one of the character combination choices included in variant component 72 by pressing the particular key 28 that lies in the position of the keypad 24 that corresponds to the position of the particular character combination choice within the displayed variant component 72. For example, referring to FIG. 4, the variant component 72 is arranged such that the character combination “us” corresponds to the key 28 containing the number 1 thereon, the character combination “ia” corresponds to the key 28 containing the number 2 thereon, the character combination “is” corresponds to the key 28 containing the number 3 thereon, and the character combination “ua” corresponds to the key 28 containing the number 4 thereon, and each of those particular character combinations can be selected by simp0ly pressing the corresponding key 28 (e.g., 4 for “ua”). According to an aspect of the invention, handheld electronic device 4 includes a routine 22, stored in memory 20 and executable by processor 16, for displaying and enabling the selection of the character combination choices generated by the text disambiguation function of handheld electronic device 4 in the manner just described.

In addition, handheld electronic device 4 is preferably provided with some type of triggering mechanism that causes handheld electronic device 4 to switch from a character entry mode to a character combination choice selection mode such that handheld electronic device 4 will treat the next depression of a key 28 as a selection of a particular character combination choice as opposed to the entry of an additional character. For example, such a trigger or trigger signal may be the passage of a predetermined amount of time that the variant portion remains displayed without entry of another character, or may be the depression of one or more keys 28 (or a special, dedicated key) in a predetermined manner (such as for a predetermined duration), sequence or combination.

Thus, as will be appreciated, the method described herein greatly simplifies the process of selecting a particular character combination choice from variant portion 72 by requiring the depression of only a single key 28 to make selections.

While specific embodiments of the invention have been described in detail, it will be appreciated by those skilled in the art that various modifications and alternatives to those details could be developed in light of the overall teachings of the disclosure. For example, while the invention has been described in connection with the a handheld electronic device that employs a text disambiguation function, it will be appreciated that the invention may also be utilized in connection with other types of electronic devices that employ a text disambiguation function, such as a personal computer or the like. Accordingly, the particular arrangements disclosed are meant to be illustrative only and not limiting as to the scope of the invention which is to be given the full breadth of the claims appended and any and all equivalents thereof.

What is claimed is:

1. A method of entering information into an electronic device, said electronic device having a text disambiguation function, a keyboard and a display, the method comprising:
generating a plurality of character combination choices using said text disambiguation function based on a first key depression sequence input into said electronic device;
displaying said character combination choices in a first spatial arrangement on said display, said first spatial arrangement substantially corresponding to a second spatial arrangement of a plurality of keys provided on a portion of said keyboard, wherein each one of said character combination choices corresponds to a particular one of said keys; and
selecting and inputting a particular one of said character combination choices when the particular one of the keys that corresponds to said particular one of said character combination choices is depressed.

2. The method according to claim 1, wherein said electronic device is a handheld electronic device.

3. The method according to claim 1, wherein said plurality of keys comprise nine keys, each of said nine keys having one of the numbers 1 through 9, respectively, provided thereon.

4. The method according to claim 3, wherein said second spatial arrangement comprises three rows, each of said rows having three of said keys.

5. The method according to claim 1, wherein a total number of said character combination choices is less than a total number of said keys such that one or more of said keys do not have a corresponding one of said character combination choices.

6. The method according to claim 1, further comprising determining whether a trigger signal has been received, said trigger signal indicating a switch from a character entry mode to a character combination choice selection mode, wherein said selecting and inputting step is performed only if it is determined that said trigger signal has been received.

7. An electronic device, comprising:
a keyboard having a plurality of keys;
a display:
a processor; and
a memory storing one or more routines executable by said processor, said one or more routines implementing a text disambiguation function and being adapted to:
generate a plurality of character combination choices using said text disambiguation function based on a key depression sequence resulting from a depression of one or more of said keys;
display said character combination choices in a first spatial arrangement on said display, said first spatial arrangement substantially corresponding to a second spatial arrangement of a number of said keys provided on a portion of said keyboard, wherein each one of said character combination choices corresponds to a particular one of said keys provided on said portion of said keyboard; and
select and input into said processor a particular one of said character combination choices when the particular one of the keys provided on said portion of said keyboard that corresponds to said particular one of said character combination choices is depressed.

8. The electronic device according to claim 7, wherein said electronic device is a handheld electronic device.

9. The electronic device according to claim 7, wherein said plurality of keys comprise nine keys, each of said nine keys having one of the numbers 1 through 9, respectively, provided thereon.

10. The electronic device according to claim 9, wherein said second spatial arrangement comprises three rows, each of said rows having three of said keys provided on said portion of said keyboard.

11. The electronic device according to claim 7, wherein a total number of said character combination choices is less than a total number of said keys provided on said portion of said keyboard such that one or more of said keys provided on said portion of said keyboard do not have a corresponding one of said character combination choices.

12. The electronic device according to claim 7, wherein said one or more routines are further adapted to determine whether a trigger signal has been received, said trigger signal indicating a switch from a character entry mode to a character combination choice selection mode, and select and input said particular one of said character combination choices only if it is determined that said trigger signal has been received.
